(19) United States
(12) Patent Application Publication
(10) Pub. No.: US 2025/0221044 A1
(43) Pub. Date: Jul. 3, 2025

(54) STRETCHABLE DISPLAY DEVICE

(71) Applicant: LG Display Co., Ltd., Seoul (KR)

(72) Inventors: Yu-Ra JEONG, Paju-si (KR); Sung-Joon MIN, Paju-si (KR); Hae-Yoon JUNG, Paju-si (KR); Ji-Ho KANG, Paju-si (KR); Myung-Sub LIM, Paju-si (KR); In-Jun LEE, Paju-si (KR)

(21) Appl. No.: 18/887,874

(22) Filed: Sep. 17, 2024

(30) Foreign Application Priority Data
Dec. 28, 2023 (KR) 10-2023-0194834

(51) Int. Cl. H01L 27/12; H01L 25/16; H01L 33/62

(52) U.S. Cl. CPC H10D 86/60; H01L 25/167; H10D 86/411; H10H 20/857

(57) ABSTRACT

A stretchable display device includes a first substrate having thereon a display area and a non-display area adjacent to the display area. The stretchable display device includes a plurality of rigid portions provided in the display area on the first substrate and spaced apart from each other in a first direction and a second direction. The stretchable display device includes a soft portion provided between adjacent rigid portions in the first direction or the second direction. The stretchable display device includes a second substrate disposed over the first substrate. A length of the soft portion is smaller than a length of the rigid portion in a direction. The rigid portion and the soft portion are rotated at a rotation angle with respect to the first direction and the second direction.

### CROSS-REFERENCE TO RELATED APPLICATION

The present application claims priority to Korean Patent Application No. 10-2023-0194834 filed in the Republic of Korea on Dec. 28, 2023, the entire contents of which are hereby expressly incorporated by reference into the present application.

### BACKGROUND

### Technical Field

The present disclosure relates to a display device, and more particularly, to a stretchable display device having high resolution.

### Description of the Related Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

### BRIEF SUMMARY

The stretchable display device is a display that can freely transform the shape of a screen without distortion even when the size of the screen is increased, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid portion in which a pixel is disposed and a soft portion in which a connection line connecting the pixels is disposed. The rigid portion may not be stretched, and the soft portion may be stretched.

Accordingly, in order to secure stretching properties and repeated stretching reliability, sufficient space for the soft portion is required, which limits the increase in the resolution of the stretchable display device.

Accordingly, the present disclosure is to provide a stretchable display device that substantially obviates one or more of the limitations and disadvantages described above and associated with the background art.

More specifically, an object of the present disclosure is to provide a stretchable display device with high resolution.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, as well as the appended drawings.

To achieve these and other aspects of the present disclosure, as embodied and broadly described herein, a stretchable display device includes a first substrate including a display area and a non-display area; a plurality of rigid portions provided in the display area on the first substrate and spaced apart from each other in a first direction and a second direction; a soft portion provided between adjacent rigid portions in the first direction or the second direction; and a second substrate disposed over the first substrate, wherein a length of the soft portion is smaller than a length of the rigid portion in a direction, and wherein the rigid portion and the soft portion is rotated at a rotation angle with respect to the first direction and the second direction.

It is to be understood that both the foregoing general description and the following detailed description are examples and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic plan view of a stretchable display device according to an embodiment of the present disclosure;

FIG. 2 is a plan view schematically illustrating a part of a stretchable display device according to the embodiment of the present disclosure;

FIGS. 3A and 3B are plan views schematically illustrating a part of a stretchable display device of another example according to the embodiment of the present disclosure;

FIG. 4 is an equivalent circuit diagram for a sub-pixel of a stretchable display device according to the embodiment of the present disclosure;

FIG. 5 is a cross-sectional view corresponding to line I-I′ of FIG. 2;

FIG. 6 is a schematic plan view of a soft portion of a stretchable display device according to an embodiment of the present disclosure;

FIG. 7A is a schematic plan view illustrating a structure of a stretchable line according to an embodiment of the present disclosure;

FIG. 7B is a schematic plan view illustrating a structure of a stretchable line according to a first comparative example;

FIG. 7C is a schematic plan view illustrating a structure of a stretchable line according to a second comparative example;

FIG. 8 is a graph showing the repeated stretching reliability of stretchable lines according to an embodiment of the present disclosure and comparative examples;

FIG. 9 is a schematic plan view of a stretchable display device according to a comparative example;

FIG. 10 is a schematic plan view of another arrangement structure of a stretchable display device according to an embodiment of the present disclosure;

FIG. 11A and FIG. 11B are plan views of other arrangement structures of a stretchable display device according to an embodiment of the present disclosure;

FIG. 12 is a schematic plan view of non-rotating rigid portions and soft portions according to an embodiment of the present disclosure;

FIG. 13 is a schematic plan view of rotating rigid portions and soft portions according to an embodiment of the present disclosure; and

FIG. 14 is a schematic cross-sectional view of a stretchable display device according to another embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, dimensions (e.g., length, width, height, thickness, radius, diameter, area, etc.), ratios, angles, numbers, number of elements, and the like disclosed in the drawings for describing the embodiments of the present disclosure are merely examples, and thus the present disclosure is not limited to the illustrated matters.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

The text “and/or” as used herein indicates that either one of the options or both options can be considered. For example, “A and/or B” means (1) Option A, or (2) Option B, or (3) Both Option A and Option B.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

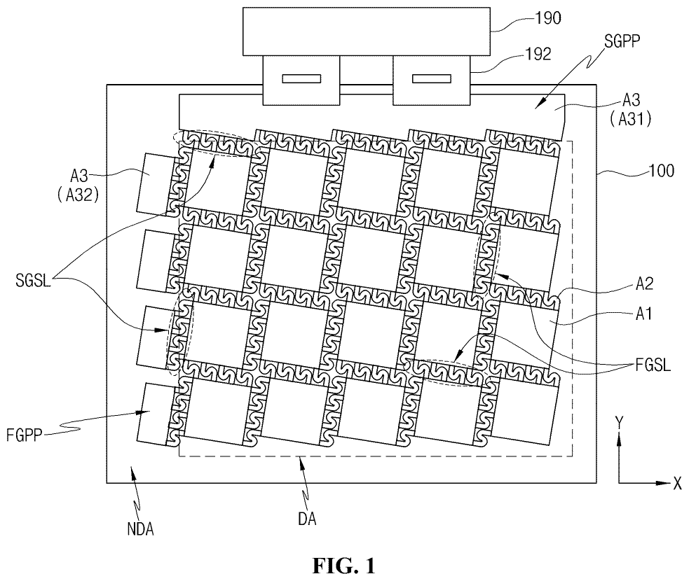

FIG. 1 is a schematic plan view of a stretchable display device according to an embodiment of the present disclosure.

In FIG. 1, a stretchable display device according to an embodiment of the present disclosure may include a display panel 100, a printed circuit board 190, and a flexible printed circuit 192.

The display panel 100 may be stretched in a first direction (X-axis direction) and a second direction (Y-axis direction) transverse to the first direction. The display panel 100 may include a display area DA displaying an image and a non-display area NDA provided on and adjacent to at least one side of the display area DA.

A rigid portion A1 corresponding to a first area and a soft portion A2 corresponding to a second area may be provided in the display area DA, and a pad portion A3 corresponding to a third area may be provided in the non-display area NDA.

The rigid portion A1 may be provided in the form of an island and may be disposed to be spaced apart from another rigid portion A1 along the first direction X and the second direction Y. FIG. 1 shows a plurality of rigid portions A1 arranged on the display panel 100 and being spaced apart from each other like an island. The rigid portion A1, for example, may have a polygonal shape. In some embodiments, the rigid portion A1 may have a substantially rectangular shape. A pixel including a plurality of sub-pixels may be provided in the rigid portion A1. Each of the plurality of sub-pixels may include a light-emitting diode, at least one thin film transistor, a plurality of lines, and a plurality of electrodes.

The soft portion A2 may be disposed between the rigid portions A1 adjacent to each other in each of the first direction X and the second direction Y. Multiple soft portions A2 may be provided between the adjacent rigid portions A1. In addition, the soft portion A2 may be disposed between the rigid portion A1 and the pad portion A3 (that is, the pad portion A32) adjacent to each other in the first direction X and between the rigid portion A1 and the pad portion A3 (that is, the pad portion A31) adjacent to each other in the second direction Y. The term ‘soft’ in the soft portion indicates that the soft portion A2 is stretchable, extendable, pliable, bendable, flexible, etc. On the other hand, the term ‘rigid’ in the rigid portion indicates that the rigid portion A1, compared to the soft portion, is less stretchable, extendable, pliable, bendable, flexible, etc. For example, rigid portions may also be stretchable to some extent but not as much as the soft portions.

A stretchable line that is a connection line connecting the adjacent pixels may be provided in the soft portion A2. The stretchable line may include a plurality of signal lines such as a gate line, a data line, a high potential line, a low potential line, an emission line, and a reference voltage line. The stretchable line is provided each soft portion A2. Referring to FIG. 1, there are a plurality of stretchable lines coupling adjacent rigid portions A1. There are also a plurality of stretchable lines coupling the rigid portion A1 to the pad portion A3. For instance, the plurality of stretchable lines shown in FIG. 1 includes a first group FGSL of stretchable lines that is coupled between adjacent rigid portions A1 and a second group SGSL of stretchable lines that is coupled between the pad portion A3 and a rigid portion A1. There are two types of pad portion A3 illustrated in FIG. 1. A first group FGPP of the pad portion A32 has a rectangular shape from a plan view, and the second group SGPP of the pad portion A31 has a saw-toothed shape from a plan view. Here, one group of stretchable lines couples the second group SGPP of the pad portion A31 with the adjacent rigid portions A1 and another group of stretchable lines couples the first group FGPP of the pad portion A32 with adjacent rigid portions A1.

The soft portion A2 may have at least one curved part. The soft portion A2 may have a curved shape, and have a substantially S-like shape. Accordingly, the stretchable line may also have a curved shape, and have a substantially S-like shape.

Meanwhile, the non-display area NDA may be an area in which an image is not displayed, and the pad portion A3 may be disposed in the non-display area NDA. A plurality of link lines extending from the plurality of signal lines disposed in the display area DA and a plurality of pads connected to ends of the plurality of link lines may be provided in the pad portion A3.

The pad portion A3 may include a first pad portion A31 and a second pad portion A32. The first pad portion A31 may correspond to the rigid portions A1 arranged in the first direction X, and the second pad portion A32 may correspond to the rigid portions A1 arranged in the second direction Y. The first pad portion A31 may be disposed on at least one of upper and lower sides of the display area DA, and the second pad portion A32 may be disposed on at least one of left and right sides of the display area DA. For example, as shown in FIG. 1, the first pad portion A31 may be disposed on the upper side of the display area DA, and the second pad portion A32 may be disposed on the left side of the display area DA.

The first pad portion A31 may be provided as one pattern corresponding to the plurality of rigid portions A1 arranged in the first direction X. That is, one first pad portion A31 may correspond to the plurality of rigid portions A1.

On the other hand, the second pad portion A32 may be separated to correspond to each of the plurality of rigid portions A1 arranged in the second direction Y. That is, a plurality of second pad portions A32 may correspond to the plurality of rigid portions A1, respectively.

However, embodiments of the present disclosure are not limited thereto. In other embodiments, the first pad portion A31 may be separated to correspond to each of the plurality of rigid portions A1 arranged in the first direction X, and the second pad portion A32 may be provided as one pattern corresponding to the plurality of rigid portions A1 arranged in the second direction Y.

In some embodiments, the rigid portion A1 and the pad portion A3 may not be stretched, and the soft portion A2 may be stretched.

Meanwhile, the flexible printed circuit 192 may be connected to the first pad portion A31 of the pad portion A3. The flexible printed circuit 192 may include a base film made of a flexible material and a driver integrated circuit chip (driver IC chip) mounted on the base film. The flexible printed circuit 192 may generate a gate signal and a data signal for displaying the image and transmit the gate signal and the data signal to the display panel 100.

In the embodiment of FIG. 1, the flexible printed circuit 192 is shown to be a chip on film (COF) type, but embodiments of the present disclosure are not limited thereto. In other embodiments, the flexible printed circuit 192 may be a chip on glass (COG) type or a tape carrier package (TCP) type.

The printed circuit board 190 may include a circuit part for controlling the driver IC chip. For example, the printed circuit board 190 may include a timing controller receiving an image signal and a plurality of timing signals, generating a plurality of control signals, and transmitting the generated control signals to the driver IC chip.

In the stretchable display device according to the embodiment of the present disclosure, the rigid portion A1 and the soft portion A2 may be disposed to be rotated with respect to the first direction X and the second direction Y. Accordingly, like the rigid portion A1 and the soft portion A2, the second pad portion A32 may also be disposed to be rotated with respect to the first direction X and the second direction Y.

Meanwhile, the first pad portion A31 may have an inclination at a side facing the display area DA with respect to the first direction X to correspond to each rigid portion A1. Therefore, the side of the first pad portion A31 facing the display area DA may have a prism or saw-toothed shape.

As described above, in the stretchable display device according to the embodiment of the present disclosure, the stretchable line may have substantially S-like shape, and the rigid portion A1 and the soft portion A2 may be disposed to be rotated, so that relatively high resolution can be realized. For example, the resolution of the stretchable display device according to the embodiment of the present disclosure may be 150 PPI or more, and this will be described in detail later.

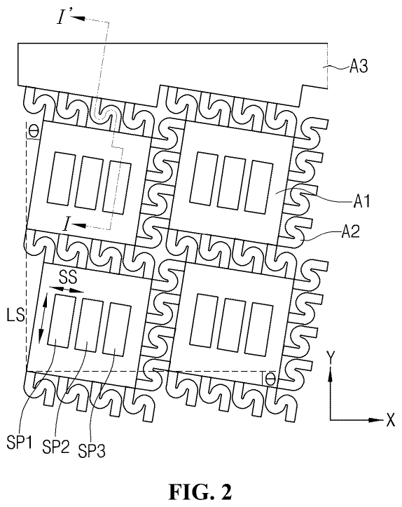

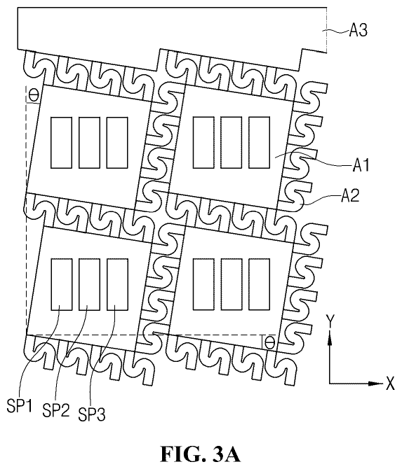

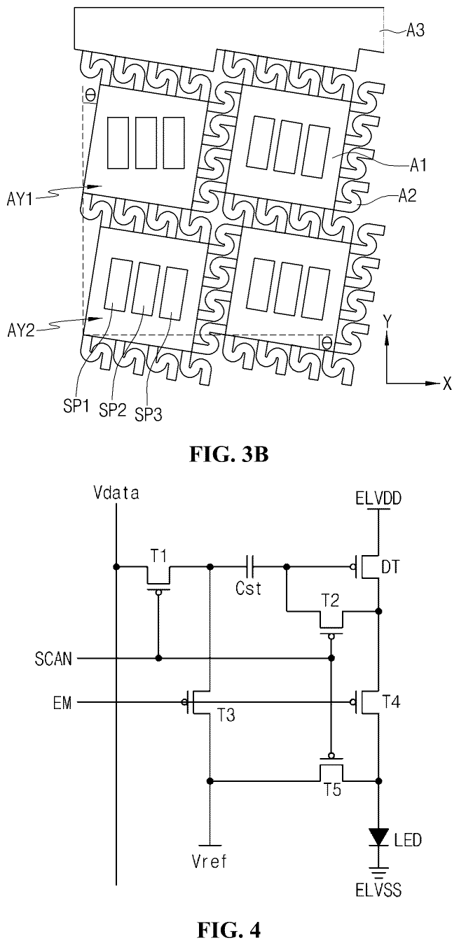

FIG. 2 is a plan view schematically illustrating a part of a stretchable display device according to the embodiment of the present disclosure, and FIGS. 3A and 3B are plan views schematically illustrating a part of a stretchable display device of another example according to the embodiment of the present disclosure.

In FIGS. 2, 3A, and 3B, the rigid portion A1 and the soft portion A2 may be rotated at a selected angle “θ” clockwise with respect to the first direction X and the second direction Y. It can also be said that the rigid portion A1 and the soft portion A2 may be rotated at a selected angle “θ” clockwise with respect to the first direction X and the second direction Y of the display panel 100.

At this time, as shown in FIG. 2, the plurality of sub-pixels SP1, SP2, and SP3 provided in each rigid portion A1 may also be rotated. For example, first, second, and third sub-pixels SP1, SP2, and SP3 may be provided in each rigid portion A1, and the first, second, and third sub-pixels SP1, SP2, and SP3 may be rotated with the same or substantially same angle in the same direction as the rigid portion A1. In this case, the configurations of the lines and electrodes provided in each rigid portion A1 may be the same as or similar to before. However, the various embodiments are not limited to such and the first, second, and third sub-pixels SP1, SP2, and SP3 may be rotated at a different angle than the rigid portion A1.

Further, as shown in FIG. 2, each sub-pixel of the plurality of sub-pixels has a first side LS (may also be referred to as a long side LS because the drawings show that it is longer than the side adjacent to the long side) and a second side SS ((may also be referred to as a short side SS because the drawings show that it is shorter than the long side adjacent to the short side). For example, the long side LS of the first sub-pixel SP1 may be rotated with respect to a second direction (e.g., y-axis direction) of the display panel 100.

Alternatively, as shown in FIG. 3A, the first, second, and third sub-pixels SP1, SP2, and SP3 may not be rotated. Accordingly, long sides of the first, second, and third sub-pixels SP1, SP2, and SP3 may be parallel to the second direction Y. In this case, the light-emitting diodes provided in the first, second, and third sub-pixels SP1, SP2, and SP3 of each rigid portion A1 may be transferred using the existing transfer method. In other embodiments, as shown in FIG. 3B, some sub-pixels on the rigid portion A1 may be rotated and other sub-pixels on the rigid portion A1 may not be rotated. For example, the first, second, and third sub-pixels SP1, SP2, and SP3 on a rigid portion AY1 may not be rotated at the selected angle “θ” even though the rigid portion AY1 is rotated at the selected angle “θ”. Accordingly, long sides of the first, second, and third sub-pixels SP1, SP2, and SP3 on the rigid portion AY1 may be parallel to the second direction Y. On the other hand, the first, second, and third sub-pixels SP1, SP2, and SP3 on a rigid portion AY2 may be rotated at the selected angle “θ”. Accordingly, long sides of the first, second, and third sub-pixels SP1, SP2, and SP3 on the rigid portion AY2 may not be aligned with Y-axis. Namely, the sub-pixels on the rigid portion AY2 may be tilted at the selected angle “θ”.

FIG. 4 is an equivalent circuit diagram for a sub-pixel of a stretchable display device according to the embodiment of the present disclosure.

In FIG. 4, one sub-pixel of the stretchable display device according to the embodiment of the present disclosure, that is, each of the first, second, and third sub-pixels SP1, SP2, and SP3 may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the gate signal SCAN and may be connected to the driving transistor DT. Specifically, a gate of the second transistor T2 may be connected to the gate signal SCAN. The source of the second transistor T2 may be connected to the first capacitor electrode of the storage capacitor Cst and the gate of the driving transistor DT. The drain of the second transistor T2 may be connected to the source of the driving transistor DT and the source of the fourth transistor T4.

The third transistor T3 may be switched according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched according to the gate signal SCAN and may be connected to the reference voltage Vref and the fourth transistor T4. Specifically, a gate of the fifth transistor T5 may be connected to the gate signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 4, as an example, each sub-pixel has a 6TIC structure including six transistors and one capacitor, but in other embodiments, each sub-pixel may have one of 2T1C, 4T1C, 5T1C, 3T2C, 4T2C, 5T2C, 6T2C, 7T1C, 7T2C, 8T1C, and 8T2C structures.

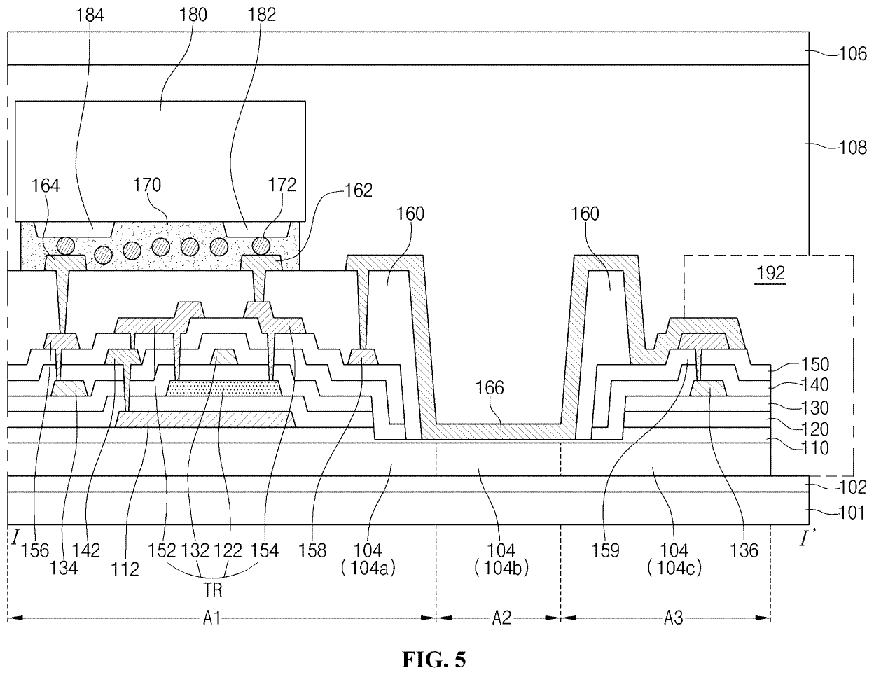

FIG. 5 is a cross-sectional view corresponding to line I-I′ of FIG. 2. FIG. 5 shows a cross-section corresponding to one sub-pixel of a stretchable display device according to the embodiment of the present disclosure and will be described with reference to FIGS. 1 to 4 together.

In FIG. 5, the stretchable display device according to the embodiment of the present disclosure may include a first substrate 101 and a second substrate 106 facing and spaced apart from each other.

The first substrate 101 and the second substrate 106, which are flexible substrates, may be formed of a soft matter or soft material with bending or stretching properties. For example, the first substrate 101 and the second substrate 106 may be formed of silicone rubber such as polydimethylsiloxane (PDMS), elastomer such as polyurethane (PU), or styrene butadiene block copolymer such as styrene butadiene styrene (SBS).

The first substrate 101 and the second substrate 106 may be formed of the same material. However, embodiments of the present disclosure are not limited thereto. In other embodiments, the first substrate 101 and the second substrate 106 may be formed of different materials.

The first substrate 101 and the second substrate 106 may have relatively low elastic modulus, that is, Young's modulus, and may have a relatively high ductile breaking rate. Here, the elastic modulus is a value representing the rate of deformation relative to the stress applied to an object. If the elastic modulus is relatively high, the hardness may be relatively high. In addition, the ductile breaking rate refers to the elongation rate at the point when the stretched object is broken or cracked. To further elaborate, the ductile breaking rate refers to an extension distance when an object to be stretched is broken or cracked. That is, the ductile breaking rate is defined as a percentage ratio of a length of an original object and a length of the stretched object when an object has been stretched sufficiently that it is considered broken. For example, if a length of an object (e.g., a substrate) is 100 cm when the object is not stretched and then, it reaches a length of 110 cm when the object has been stretched enough that it becomes broken or cracked at this length, then it has been stretched to 110% of its original length. In this case, the ductile breaking rate of the object is 110%. The number could thus also be called a ductile breaking ratio since it is a ratio of the stretched length as the numerator compared to the original unstretched length as the denominator at the time the break occurs.

For example, each of the first substrate 101 and the second substrate 106 may have the elastic modulus of several MPa to hundreds of MPa and the ductile breaking rate of about 100% or more. In addition, each of the first substrate 101 and the second substrate 106 may have a thickness of about 10 μm to about 1 mm. However, embodiments of the present disclosure are not limited thereto.

A rigid portion A1 corresponding to the first area, a soft portion A2 corresponding to the second area, and a pad portion A3 corresponding to the third area may be provided on the first substrate 101 and the second substrate 106.

A first adhesive layer 102 may be provided on an inner surface of the first substrate 101, and a base substrate 104 may be provided on the first adhesive layer 102.

The first adhesive layer 102 may attach the first substrate 101 and the base substrate 104. The first adhesive layer 102 may be formed of an acryl-based, silicon-based, or urethane-based adhesive. For example, the first adhesive layer 102 may be optically clear adhesive (OCA) that is formed and attached in the form of a film or optically clear resin (OCR) that is cured after applying a liquid material.

The base substrate 104 may include a first base portion 104a, a second base portion 104b, and a third base portion 104c. The first base portion 104a may be disposed to correspond to the rigid portion A1, the second base portion 104b may be disposed to correspond to the soft portion A2, and the third portion 104c may be disposed to correspond to the pad portion A3.

The first base portion 104a may be provided in a plate shape in the display area DA and may serve to support and protect components of the plurality of sub-pixels SP1, SP2, and SP3. The first base portion 104a may be plural, and the plurality of first base portions 104a may be spaced apart from each other in the first direction X and the second direction Y.

The second base portion 104b may be provided between the first base portion 104a and the third base portion 104c. Additionally, the second base portion 104b may be provided between the first base portions 104a adjacent to each other in the display area DA.

The second base portion 104b may include at least one curved part and may serve to support and protect a stretchable line 166.

The third base portion 104c may be provided in a plate shape in the non-display area NDA, and pads 136 and 159 connected to the flexible printed circuit 192 may be provided over the third base portion 104c.

The first, second, and third base portions 104a, 104b, and 104c adjacent to each other may be connected and provided as one-body.

The base substrate 104 may be formed of a rigid material having lower flexibility than the soft material of the first substrate 101. For example, the base substrate 104 may be formed of a polyimide (PI) resin or epoxy resin.

The base substrate 104 may have relatively high clastic modulus, and the elastic modulus of the base substrate 104 may be higher than the clastic modulus of the first substrate 101. For example, the elastic modulus of the base substrate 104 may be more than 1,000 times higher than the elastic modulus of the first substrate 101, but embodiments of the present disclosure are not limited thereto.

A first buffer layer 110 may be provided on the base substrate 104. The first buffer layer 110 may block permeation of moisture or oxygen from the outside to protect the components of the plurality of sub-pixels SP1, SP2, and SP3.

The first buffer layer 110 may be formed as a single layer or multiple layers of an inorganic insulating material. The inorganic insulating material of the first buffer layer 110 may include silicon nitride (SiNx), silicon oxide (SiOx), or silicon oxynitride (SiON).

In order to prevent or reduce damage of the first buffer layer 110 such as cracks due to stretching, the first buffer layer 110 may be removed in the soft portion A2 to substantially correspond to the rigid portion A1 and the pad portion A3 and may be disposed over the first base portion 104a and the third base portion 104c of the base substrate 104. Meanwhile, to control the thickness and hardness of the soft portion A2, the first buffer layer 110 may be partially provided with a relatively thin thickness over the second base portion 104b.

In other embodiments, the first buffer layer 110 may be omitted.

A light blocking layer 112 may be provided on the first buffer layer 110 of the rigid portion A1. The light blocking layer 112 may be formed of a conductive material such as metal. For example, the light blocking layer 112 may be formed of at least one of aluminum (Al), copper (Cu), molybdenum (Mo), titanium (Ti), chromium (Cr), nickel (Ni), tungsten (W), or an alloy thereof. The light blocking layer 112 may have a single-layered structure or a multiple-layered structure.

A second buffer layer 120 may be provided on the light blocking layer 112 of the rigid portion A1. The second buffer layer 120 may be formed as a single layer or multiple layers of an inorganic insulating material. The inorganic insulating material of the second buffer layer 120 may include silicon nitride (SiNx), silicon oxide (SiOx), or silicon oxynitride (SiON).

In addition, the second buffer layer 120 may be provided on the first buffer layer 110 of the pad portion A3 and may not be provided in the soft portion A2.

A semiconductor layer 122 may be provided on the second buffer layer 120 of the rigid portion A1. The semiconductor layer 122 may overlap the light blocking layer 112, and the light blocking layer 112 may block light incident on the semiconductor layer 122 and prevent or reduce the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both ends of the semiconductor layer 122 may be doped with impurities.

A gate insulation layer 130 may be provided on the semiconductor layer 122 of the rigid portion A1. The gate insulation layer 130 may be formed as a single layer or multiple layers of an inorganic insulating material. The inorganic insulating material of the gate insulation layer 130 may include silicon nitride (SiNx), silicon oxide (SiOx), or silicon oxynitride (SiON).

In addition, the gate insulation layer 130 may be provided on the second buffer layer 120 of the pad portion A3 and may not be provided in the soft portion A2.

A gate electrode 132 and a first pad 134 may be provided on the gate insulation layer 130 of the rigid portion A1.

The gate electrode 132 may overlap the semiconductor layer 122 and may be disposed to correspond to the central part of the semiconductor layer 122. Accordingly, the gate electrode 132 may also overlap the light blocking layer 112.

The first pad 134 may be spaced apart from the semiconductor layer 122 and the light blocking layer 112.

In addition, a source pad 136 may be provided on the gate insulation layer 130 of the pad portion A3.

The gate electrode 132, the first pad 134, and the source pad 136 may be formed of a conductive material such as metal. For example, the gate electrode 132, the first pad 134, and the source pad 136 may be formed of at least one of aluminum (Al), copper (Cu), molybdenum (Mo), titanium (Ti), chromium (Cr), nickel (Ni), tungsten (W), or an alloy thereof. The gate electrode 132, the first pad 134, and the source pad 136 may have a single-layered structure or a multiple-layered structure.

A first interlayer insulation layer 140 may be provided on the gate electrode 132 and the first pad 134 of the rigid portion A1. In the rigid portion A1, the first interlayer insulation layer 140 may cover and contact at least one side surfaces of the first buffer layer 110, the second buffer layer 120, and the gate insulation layer 130.

The first interlayer insulation layer 140 may be formed as a single layer or multiple layers of an inorganic insulating material. The inorganic insulating material of the first interlayer insulation layer 140 may include silicon nitride (SiNx), silicon oxide (SiOx), or silicon oxynitride (SiON).

In addition, the first interlayer insulation layer 140 may be provided on the source pad 136 of the pad portion A3 and may not be provided in the soft portion A2. In the pad portion A3, the first interlayer insulation layer 140 may cover and contact at least one side surfaces of the first buffer layer 110, the second buffer layer 120, and the gate insulation layer 130.

An auxiliary electrode 142 may be provided on the first interlayer insulation layer 140 of the rigid portion A1. The auxiliary electrode 142 may overlap the light blocking layer 112 and may be in contact with the light blocking layer 112 through a contact hole provided in the second buffer layer 120, the gate insulation layer 130, and the first interlayer insulation layer 140. The auxiliary electrode 142 may be spaced apart from the semiconductor layer 122, the gate electrode 132, and the first pad 134.

The auxiliary electrode 142 may be formed of a conductive material such as metal. For example, the auxiliary electrode 142 may be formed of at least one of aluminum (Al), copper (Cu), molybdenum (Mo), titanium (Ti), chromium (Cr), nickel (Ni), tungsten (W), or an alloy thereof. The auxiliary electrode 142 may have a single-layered structure or a multiple-layered structure.

A second interlayer insulation layer 150 may be provided on the auxiliary electrode 142 of the rigid portion A1. The second interlayer insulation layer 150 may be formed as a single layer or multiple layers of an inorganic insulating material. The inorganic insulating material of the second interlayer insulation layer 150 may include silicon nitride (SiNx), silicon oxide (SiOx), or silicon oxynitride (SiON).

In addition, the second interlayer insulation layer 150 may be provided on the first interlayer insulation layer 140 of the pad portion A3 and may not be provided in the soft portion A2.

A source electrode 152, a drain electrode 154, a connection electrode 156, and a second pad 158 may be provided on the second interlayer insulation layer 150 of the rigid portion A1.

The source electrode 152 and the drain electrode 154 may be spaced apart from each other with the gate electrode 132 positioned therebetween and may be in contact with both ends of the semiconductor layer 122 through contact holes provided in the first and second interlayer insulation layers 140 and 150 and the gate insulation layer 130. In addition, the source electrode 152 may overlap the auxiliary electrode 142 and may be in contact with the auxiliary electrode 142 through a contact hole provided in the second interlayer insulation layer 150.

The semiconductor layer 122, the gate electrode 132, the source electrode 152, and the drain electrode 154 may constitute a thin film transistor TR.

The connection electrode 156 may be spaced apart from the thin film transistor TR. The connection electrode 156 may overlap the first pad 134 and may be in contact with the first pad 134 through a contact hole provided in the first and second interlayer insulation layers 140 and 150.

The second pad 158 may be spaced apart from the thin film transistor TR and may be disposed to be adjacent to an edge of the rigid portion A1.

An auxiliary pad 159 may be provided on the second interlayer insulation layer 150 of the pad portion A3. The auxiliary pad 159 may overlap the source pad 136 and may be in contact with the source pad 136 through a contact hole provided in the first and second interlayer insulation layers 140 and 150.

The source electrode 152, the drain electrode 154, the connection electrode 156, the second pad 158, and the auxiliary pad 159 may be formed of a conductive material such as metal. For example, the source electrode 152, the drain electrode 154, the connection electrode 156, the second pad 158, and the auxiliary pad 159 may be formed of at least one of aluminum (Al), copper (Cu), molybdenum (Mo), titanium (Ti), chromium (Cr), nickel (Ni), tungsten (W), or an alloy thereof. The source electrode 152, the drain electrode 154, the connection electrode 156, the second pad 158, and the auxiliary pad 159 may have a single-layered structure or a multiple-layered structure.

A planarization layer 160 may be provided on the source electrode 152, the drain electrode 154, the connection electrode 156, and the second pad 158 of the rigid portion A1. The planarization layer 160 may eliminate a step difference due to the layers thereunder and may have a substantially flat top surface. The planarization layer 160 may be formed of an organic insulating material such as photosensitive acrylic polymer (photo acryl).

In addition, the planarization layer 160 may be provided on the second interlayer insulation layer 150 of the pad portion A3 and may not be provided in the soft portion A2. In the pad portion A3, the planarization layer 160 may expose the auxiliary pad 159 without covering it and may be spaced apart from the auxiliary pad 159. At this time, the planarization layer 160 may also expose a top surface of the second interlayer insulation layer 150 in the pad portion A3.

A first contact electrode 162, a second contact electrode 164, and the stretchable line 166 may be provided on the planarization layer 160 of the rigid portion A1.

The first contact electrode 162, the second contact electrode 164, and the stretchable line 166 may be formed of a conductive material such as metal. For example, the first contact electrode 162, the second contact electrode 164, and the stretchable line 166 may be formed of at least one of aluminum (Al), copper (Cu), molybdenum (Mo), titanium (Ti), chromium (Cr), nickel (Ni), tungsten (W), or an alloy thereof. The first contact electrode 162, the second contact electrode 164, and the stretchable line 166 may have a single-layered structure or a multiple-layered structure.

The first contact electrode 162 may overlap the drain electrode 154 and may be in contact with the drain electrode 154 through a contact hole provided in the planarization layer 160. The second contact electrode 164 may overlap the connection electrode 156 and may be in contact with the connection electrode 156 through a contact hole provided in the planarization layer 160.

The stretchable line 166 may overlap the second pad 158 and may be in contact with the second pad 158 through a contact hole provided in the planarization layer 160.

The stretchable line 166 may extend into and be provided in the soft portion A2 and the pad portion A3. At this time, the stretchable line 166 may be in contact with top and side surfaces of the planarization layer 160 in the rigid portion A1 and the pad portion A3.

In the soft portion A2, the stretchable line 166 may be in contact with the first buffer layer 110. Alternatively, when the first buffer layer 110 is completely removed in the soft portion A2, the stretchable line 166 may be in contact with the base substrate 104.

In the pad portion A3, the stretchable line 166 may overlap and cover the auxiliary pad 159. Therefore, the stretchable line 166 may be in contact with top and side surfaces of the auxiliary pad 159. Additionally, in the pad portion A3, the stretchable line 166 may be in contact with a top surface of the second interlayer insulation layer 150.

Meanwhile, although not shown in the figure, a bank layer may be further provided on the first contact electrode 162, the second contact electrode 164, and the stretchable line 166 in the rigid portion A1. The bank layer may expose at least parts of the first contact electrode 162 and the second contact electrode 164 and may cover the stretchable line 166.

An adhesive layer 170 may be provided on the first and second contact electrodes 162 and 164 of the rigid portion A1. The adhesive layer 170 may be an anisotropic conductive film (ACF) including an insulating base member and a plurality of conductive balls 172 dispersed in the insulating base member.

When heat or pressure is applied to the adhesive layer 170, in an area where the heat or pressure is applied, the conductive balls 172 may be electrically connected, so that the adhesive layer 170 may have a conductive property, and in an area where the heat or pressure is not applied, the adhesive layer 170 may have an insulating property.

A light-emitting element 180 may be provided on the adhesive layer 170. The light-emitting element 180 may include a first electrode 182 and a second electrode 184.

Here, the first electrode 182 may be a p-electrode, and the second electrode 184 may be an n-electrode. The first electrode 182 may be an anode, and the second electrode 184 may be a cathode. However, embodiments of the present disclosure are not limited thereto.

Alternatively, in other embodiments, the first electrode 182 may be an n-electrode, and the second electrode 184 may be a p-electrode. In this case, the first electrode 182 may be a cathode, and the second electrode 184 may be an anode.

The light-emitting element 180 may be provided in the form of a micro light-emitting diode chip (micro LED chip or uLED chip) including the n-electrode, an n-type layer, an active layer, a p-type layer, and the p-electrode. The light-emitting element 180 may have a flip-chip structure in which the n-electrode and the p-electrode are provided on the same side (for example, a side facing the first substrate 101) and light is emitted through a side opposite to the side provided with the n-electrode and the p-electrode (for example, a side facing the second substrate 106).

However, embodiments of the present disclosure are not limited thereto. The light-emitting element 180 may have a lateral structure in which the n-electrode and the p-electrode are provided on the same side and light is emitted through the same side provided with the n-electrode and the p-electrode or may have a vertical structure in which the n-electrode and the p-electrode are provided on opposite sides, respectively.

The first electrode 182 of the light-emitting element 180 may overlap the first contact electrode 162, and the second electrode 184 of the light-emitting element 180 may overlap the second contact electrode 164. The first electrode 182 may be electrically connected to the first contact electrode 162 through the conductive balls 172 of the adhesive layer 170, and the second electrode 184 may be electrically connected to the second contact electrode 164 through the conductive balls 172 of the adhesive layer 170.

Meanwhile, a flexible printed circuit 192 may be attached onto the stretchable line 166 of the pad portion A3. The flexible printed circuit 192 may be connected to the source pad 136 through the stretchable line 166 and the auxiliary pad 159.

A second adhesive layer 108 may be provided on the light-emitting element 180 and the stretchable line 166, and the second substrate 106 may be disposed on the second adhesive layer 108.

The second adhesive layer 108 may attach the light-emitting element 180 and the stretchable line 166 with the second substrate 106. The second adhesive layer 108 may be formed of the same material as the first adhesive layer 102.

The second adhesive layer 108 may have substantially the same thickness as the first adhesive layer 102.

In the stretchable display device according to the embodiment of the present disclosure, to realize high resolution, an area of the soft portion A2 may be minimized or reduced, and a length of the soft portion A2 may also be decreased. The area of the soft portion A2 may be smaller than an area of the rigid portion A1, and the length of the soft portion A2 may be shorter than a length of the rigid portion A1. Accordingly, since a length of the stretchable line 166 provided in the soft portion A2 may also be shortened, it is beneficial that the stretchable line 166 has a structure having relatively excellent stretching properties and repeated stretching reliability.

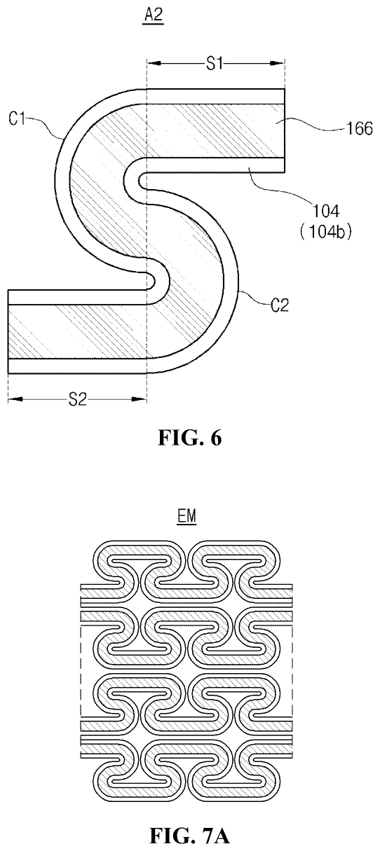

Such a structure of a stretchable line according to an embodiment of the present disclosure will be described with reference to FIG. 6.

FIG. 6 is a schematic plan view of a soft portion of a stretchable display device according to an embodiment of the present disclosure, and will be described with reference to FIGS. 1 to 5 together.

As shown in FIG. 6, in the stretchable display device according to the embodiment of the present disclosure, the soft portion A2 may have a curved shape including a straight part and may have a substantially S-like shape.

Specifically, the soft portion A2 may include first and second straight parts S1 and S2 (also referred to as first and second straight portions S1 and S2) and first and second curved parts C1 and C2 (also referred to as first and second curved portions C1 and C2). The first and second curved parts C1 and C2 may be interposed between the first straight part S1 and the second straight part S2 and may be disposed convexly in opposite directions.

The first straight part S1 may be connected to one rigid portion A1, and the second straight part S2 may be connected to another rigid portion A1 adjacent to the one rigid portion A1. Alternatively, the first straight part S1 may be connected to the first pad portion A31 and the second straight part S2 may be connected to the rigid portion A1 adjacent to the first pad portion A31, or the first straight part S1 may be connected to the rigid portion A1 adjacent to the second pad portion A32 and the second straight part S2 may be connected to the second pad portion A32.

The soft portion A2 may include the base substrate 104, that is, the second base portion 104b, and the stretchable line 166. The second base portion 104b and the stretchable line 166 may have substantially the same shape as the soft portion A2. That is, the second base portion 104b and the stretchable line 166 may have a curved shape, and may have a substantially S-like shape.

Here, the second base portion 104b and the stretchable line 166 may have substantially the same length and straight distance as the soft portion A2, and the second base portion 104b may have a wider width and area than the stretchable line 166 when seen from a plan view. However, embodiments of the present disclosure are not limited thereto. Alternatively, in other embodiments, the stretchable line 166 may have a wider width and area than the second base portion 104b.

The stretchable line 166 of the S-like shape may be a part of an omega structure (e.g., the omega symbol Ω shape). Accordingly, the soft portion A2 of the S-like shape may also be a part of an omega structure. Since the stretchable line of the omega structure has a relatively large ratio of length to straight line, the stretchable line of the omega structure may have relatively high stretching properties.

The ratio of length to straight line is a value that a total length of the stretchable line is divided by a straight distance between both ends of the stretchable line. As the ratio of length to straight line increases, the elongation rate may increase, and the stretching properties may be high.

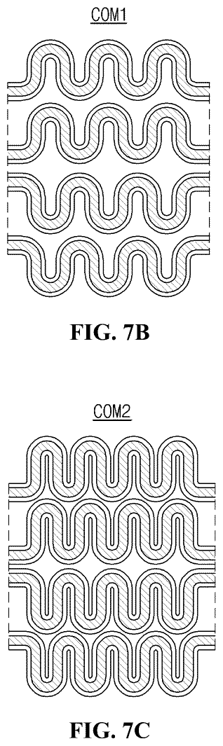

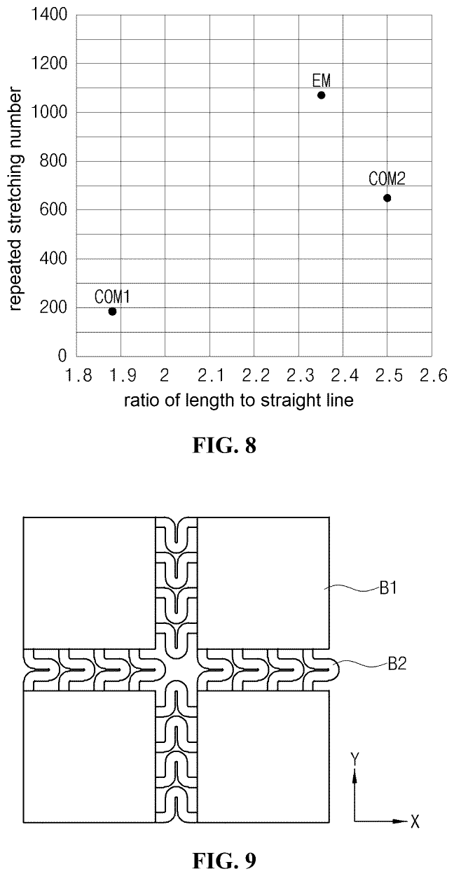

In addition, the stretchable line of the omega structure may have higher repeated stretching reliability compared to a stretchable line of a wave structure having the same ratio of length to straight line. The ratio of length to straight line and repeated stretching reliability of such a stretchable line will be described in detail with reference to FIGS. 7A to 7C and FIG. 8.

FIG. 7A is a schematic plan view illustrating a structure of a stretchable line according to an embodiment of the present disclosure, FIG. 7B is a schematic plan view illustrating a structure of a stretchable line according to a first comparative example, and FIG. 7C is a schematic plan view illustrating a structure of a stretchable line according to a second comparative example.

In FIG. 7A, the stretchable line according to the embodiment EM of the present disclosure may have a substantially omega structure (e.g., includes the omega symbol Ω shape). For example, the stretchable line according to the embodiment EM of the present disclosure may have a structure in which two omega shapes are connected to each other (e.g., ΩΩ shape).

Meanwhile, in FIG. 7B, the stretchable line according to the first comparative example COM1 may have a first wave structure (e.g., sine wave shape), and in FIG. 7C, the stretchable line according to the second comparative example COM2 may have a second wave structure.

Here, the second wave structure of the second comparative example COM2 may have a greater number of wave shapes than the first wave structure of the first comparative example COM1. For example, the first wave structure may have three wave shapes, and the second wave structure may have four wave shapes.

The ratio of length to straight line of the stretchable line according to the embodiment EM of the present disclosure may be about 2.35, the ratio of length to straight line of the stretchable line according to the first comparative example COM1 may be about 1.88, and the ratio of length to straight line of the stretchable line according to the second comparative example COM2 may be about 2.5.

The repeated stretching reliability of the stretchable lines having the ratios of length to straight line will be described with reference to FIG. 8.

FIG. 8 is a graph showing the repeated stretching reliability of stretchable lines according to an embodiment of the present disclosure and comparative examples. FIG. 8 shows the number of repeated stretching in relation to the ratio of length to straight line when the resistance of the stretchable line increases by 5% by repeatedly stretching the length of the stretchable line by 20%. Here, the larger the number of repeated stretching is, the higher the repeated stretching reliability is.

In FIG. 8, it can be seen that the stretchable line of the omega structure according to the embodiment EM of the present disclosure may have the greater ratio of length to straight line and higher repeated stretching reliability than the stretchable line of the first wave structure according to the first comparative example COM1.

In addition, it can be seen that the stretchable line of the omega structure according to the embodiment EM of the present disclosure may have the somewhat smaller ratio of length to straight line but higher repeated stretching reliability than the stretchable line of the second wave structure according to the second comparative example COM2.

Accordingly, in the present disclosure, the omega structure having the relatively higher stretching properties and repeated stretchable reliability may be applied to the stretchable line.

At this time, to realize the high resolution, a part of the omega structure may be applied to the stretchable line, and the stretchable line may have the substantially S-like shape, thereby securing the stretching properties and the repeated stretchable reliability while minimizing or reducing the length of the stretchable line.

The stretchable line according to the embodiment of the present disclosure, which is the part of the omega structure, may have the ratio of length to straight line of about 2.12.

On the other hand, FIG. 9 is a schematic plan view of a stretchable display device according to a comparative example. In FIG. 9, the soft portion B2, in which the stretchable line is disposed, may be provided between adjacent rigid portions B1, and the stretchable line may include a part of the wave structure.

The stretchable line according to the comparative example, which is the part of the wave structure, may have the ratio of length to straight line of about 2.05, which is smaller than the ratio of length to the straight line of the stretchable line according to the embodiment of the present disclosure, which is the part of the omega structure.

Accordingly, the stretchable line according to the embodiment of the present disclosure, which is the part of the omega structure, may have improved stretching properties and repeated stretching reliability compared to the stretchable line according to the comparative example, which is the part of the wave structure, and may be suitable for a high resolution display device.

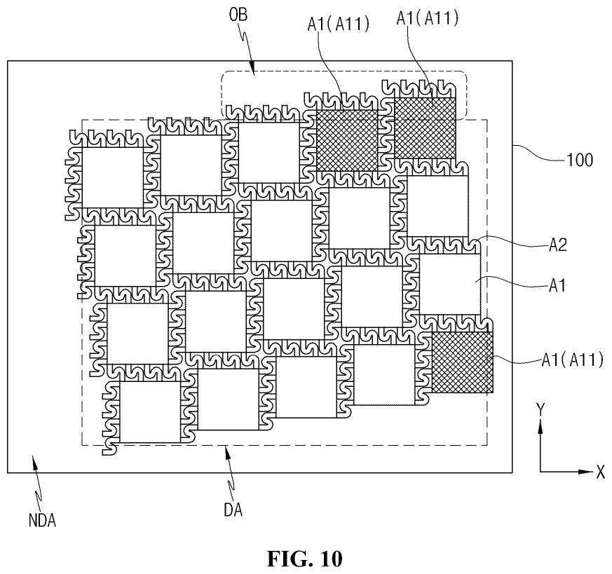

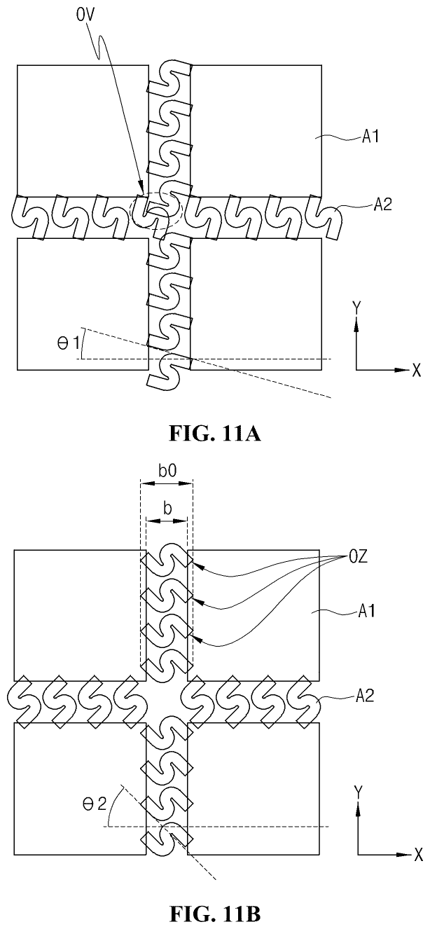

Additionally, in the stretchable display device according to an embodiment of the present disclosure having the stretchable line of such a structure, in order to realize high resolution, the rigid portion A1 and the soft portion A2 may be rotated at a selected angle “θ” with respect to the first direction X and the second direction Y. This will be described with reference to FIG. 10 and FIGS. 11A and 11B.

FIG. 10 is a schematic plan view of another arrangement structure of a stretchable display device according to an embodiment of the present disclosure. FIG. 10 shows a configuration in which the rigid portions A1 and the soft portion A2 are disposed without rotating and will be described with reference to FIG. 1.

In FIG. 10, the rigid portions A1 and the soft portions A2 may be disposed without rotating with respect to the first direction X and the second direction Y in the display panel 100. In this case, some rigid portions A1 may be partially out of the display area DA and may be partially disposed in the non-display area NDA. For instance, as shown in area OB, some parts of the rigid portions A1 and the soft portion A2 are disposed in the non-display area NDA. These parts in area OB overlap with the non-display area NDA from a plan view.

Accordingly, the rigid portion All out of the display area DA does not contribute to the resolution. The resolution of the arrangement structure of FIG. 10 may decrease compared to the resolution of the arrangement structure of FIG. 1 for the same area.

Meanwhile, in the stretchable display device according to the embodiment of the present disclosure, when the rigid portion A1 does not rotate and the soft portion A2 is rotated, it is difficult to implement the stretchable display device due to structural limitations, and this will be described with reference to FIG. 11A and FIG. 11B.

FIG. 11A and FIG. 11B are plan views of other arrangement structures of a stretchable display device according to an embodiment of the present disclosure and show configurations in which the rigid portion A1 does not rotate and the soft portion A2 is rotated. Here, a rotation angle of the soft portion A2 of FIG. 11B may be greater than a rotation angle of the soft portion A2 of FIG. 11A.

In FIG. 11A, in a situation when the rigid portion A1 does not rotate and the soft portion A2 rotates, and the rotation angle θ1 is relatively small, there may be an area OV in which the stretchable lines overlap each other, so that it is impossible to arrange the stretchable lines.

Additionally, in FIG. 11B, in a situation when the rigid portion A1 does not rotate and the soft portion A2 rotates, and the rotation angle θ2 is relatively large (e.g., greater compared to θ1; θ2>θ1), both ends of each stretchable line may overlap the rigid portion A1 (see area OZ where the soft portions A2 and the rigid portions A1 overlap with each other from a plan view), and thus a real length “b” of the stretchable line, which is a part that is disposed in a separation distance between the adjacent rigid portions A1, may be shorter than the original length “b0” of the stretchable line.

Therefore, the ratio of light to straight line may decrease, and the stretching properties may be lowered.

As described above, in the stretchable display device according to the embodiment of the present disclosure, the rigid portion A1 and the soft portion A2 may be rotated at the selected angle “θ” with respect to the first direction X and the second direction Y. At this time, as shown in FIG. 6, the second base portion 140b and the stretchable line 166 having substantially the same shape as the soft portion A2 may also be rotated at the same rotation angle “θ” in the same direction as the soft portion A2, and the rotation angle “θ” may be calculated as described below.

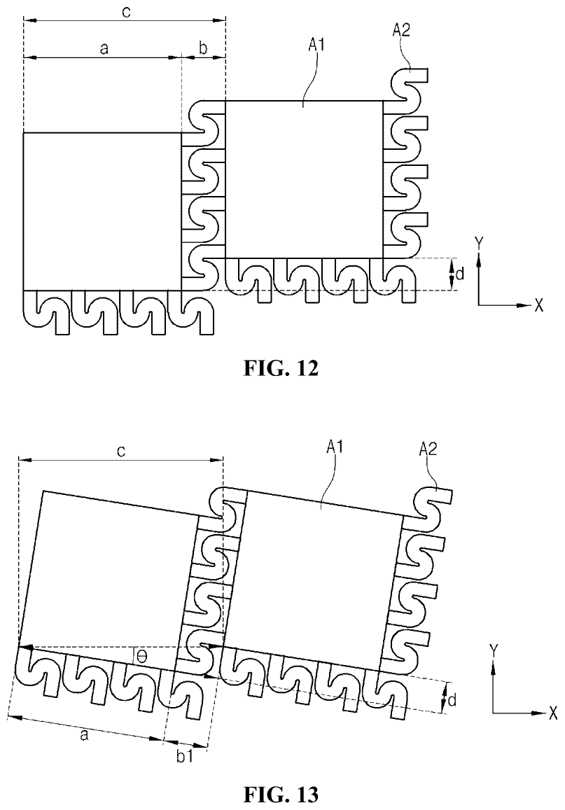

FIG. 12 is a schematic plan view of non-rotating rigid portions and soft portions according to an embodiment of the present disclosure, and FIG. 13 is a schematic plan view of rotating rigid portions and soft portions according to an embodiment of the present disclosure. FIGS. 12 and 13 show lengths of respective components and will be described based on adjacent two rigid portions A1 in the first direction X and soft portions A2 therebetween.

In FIG. 12, one rigid portion A1 and one soft portion A2 may form one unit, and when the rigid portion A1 and the soft portion A2 are not rotated, a unit length “c” (in the x-axis direction) is the sum of a length “a” of the rigid portion A1 and a length “b” of the soft portion A2.

That is, c=a+b. Here, units of “a,” “b,” and “c” may be a meter system and μm.

The unit length “c” may depend on the resolution “R.” The resolution “R” may be expressed in PPI (pixel per inch), which is the number of pixels per inch, and the unit length “c” is a value of dividing 1 inch (25,400 μm) by the resolution “R.”

That is, c=25400/R.

For example, when the resolution “R” is 100 PPI, and the unit length “c” may be 254 μm. At this time, when the rigid portion A1 and the soft portion A2 do not rotate, the length “a” of the rigid portion A1 may be 127 μm, and the length “b” of the soft portion b may be 127 μm.

Meanwhile, in the embodiment of the present disclosure, since the stretchable line and the soft portion A2 are the part of the omega structure to have the substantially S-like shape, one end and another end of each of the stretchable line and the soft portion A2 may be spaced apart from each other in the second direction Y. Accordingly, two rigid portions A1 adjacent to each other in the first direction X may be shifted from each other with a separation distance “d” in the second direction Y. For example, the separation distance “d” may be 20 μm.

Next, in FIG. 13, when the rigid portion A1 and the soft portion A2 are rotated at the rotation angle “θ” clockwise with respect to the first direction X and the second direction Y, the unit length “c” may correspond to a distance between ends of two rigid portions A1 adjacent to each other in the first direction X (in the x-axis direction).

That is, c=d/sin θ. Here, the unit of the rotation angle “θ” may be degrees.

Accordingly, the rotation angle “θ” may be θ=arcsin (d/c).

At this time, as mentioned above, since c=25400/R, the rotation angle “θ” may be θ=arcsin (d·R/25400).

In addition, regarding the length “b1” of the rotated soft portion A2 of FIG. 13, since tan θ=d/(a+b1), the length “b1” of the rotated soft portion A2 may be b1=(d/tan θ)−a.

Accordingly, in the stretchable display device according to the embodiment of the present disclosure, values obtained by calculating the length “b” of the non-rotated soft portion A2, the length “b1” of the rotated soft portion A2, and the rotation angle “θ” for each resolution “R” are shown in Table 1. Here, the length “a” of the rigid portion A1 may be 127 μm, and the separation distance “d” may be 20 μm.

TABLE 1

| R(PPI) | c(μm) | a(μm) | b(μm) | θ | b1(μm) |
|---|---|---|---|---|---|
| 100 | 254 | 127 | 127 | 0 | |
| 150 | 169.3 | 127 | 42.3 | 6.78 | 41.2 |
| 160 | 158.8 | 127 | 31.8 | 7.24 | 30.4 |
| 170 | 149.4 | 127 | 22.4 | 7.69 | 21.1 |
| 180 | 141.1 | 127 | 14.1 | 8.15 | 12.7 |

In Table 1, when the resolution “R” is 180 PPI, the length “b1” of the rotated soft portion A2 may be smaller than 20 μm. In this case, the area for disposing the stretchable line cannot be secured. Thus, if the resolution “R” is higher than 170 PPI, the stretchable display device cannot be implemented.

Accordingly, in the embodiment of the present disclosure, a method of implementing the resolution of the stretchable display device from 150 PPI to 170 PPI may be described. At this time, the rotation angle “θ” may be 5 degrees to 10 degrees. In some embodiments, it may be beneficial to have the rotation angle “θ” be 6 degrees to 8 degrees.

Meanwhile, the length “b” of the non-rotated soft portion A2 may have a greater value than the length “b1” of the rotated soft portion A2. However, when the rigid portion A1 and the soft portion A2 do not rotate, as shown in FIG. 10, some rigid portions A11 may be out of the display area DA, and thus the resolution of the display device in which the rigid portion A1 and the soft portion A2 rotate may be lower than the resolution of the display device in which the rigid portion A1 and the soft portion A2 do not rotate.

As described above, in the stretchable display device according to the embodiment of the present disclosure, by configuring the stretchable line and the soft portion A2 as the part of the omega structure and rotating the rigid portion A1, the soft portion A2, and the stretchable line, high resolution of 150 PPI to 170 PPI may be realized.

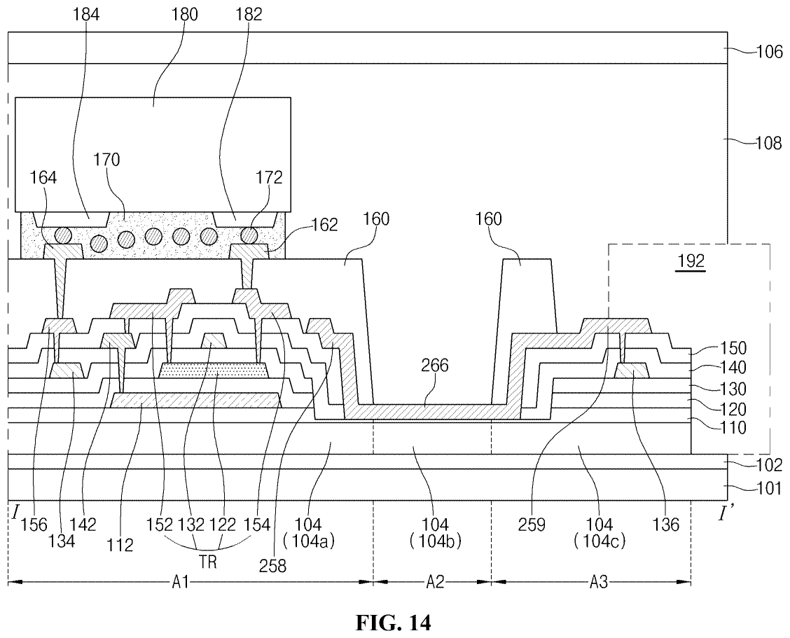

Further, in the present disclosure, by reducing the area of the rigid portion, higher resolution may be implemented. Such a stretchable display device according to another embodiment of the present disclosure will be described in detail with reference to FIG. 14.

FIG. 14 is a schematic cross-sectional view of a stretchable display device according to another embodiment of the present disclosure. FIG. 14 shows a cross-section corresponding to line I-I′ of FIG. 2 and will be described with reference to FIG. 5 together. The stretchable display device according to another embodiment of the present disclosure has substantially the same configuration as that of the previous embodiment, except for the stretchable line. The same parts as that of the previous embodiment are designated by the same reference signs, and explanation for the same parts may be shortened or omitted.

As shown in FIG. 14, in the stretchable display device according to another embodiment of the present disclosure, the stretchable line 266 may be formed of the same material and on the same layer as the source electrode 152 and the drain electrode 154.

Specifically, the source electrode 152, the drain electrode 154, the connection electrode 156, the second pad 258, and the stretchable line 266 may be provided on the second interlayer insulation layer 150 of the rigid portion A1.

The stretchable line 266 may be in direct contact with the second pad 258 and may be formed as one body. The stretchable line 266 may extend and be provided in the soft portion A2 and the pad portion A3. At this time, the stretchable line 266 may be in direct contact with the auxiliary pad 259 in the pad portion A3 and may be formed as one body.

The stretchable line 266 may be in contact with the top and side surfaces of the second interlayer insulation layer 150 in the rigid portion A1 and the pad portion A3 and may also be in contact with the side surface of the first interlayer insulation layer 140.

In addition, the stretchable line 266 may be in contact with the first buffer layer 110 in the soft portion A2. Alternatively, when the first buffer layer 110 is completely removed in the soft portion A2, the stretchable line 266 may be in contact with the base substrate 104.

The planarization layer 160 may be provided on the source electrode 152, the drain electrode 154, the connection electrode 156, the second pad 258, and the stretchable line 266 of the rigid portion A1. In addition, the planarization layer 160 may be provided on the stretchable line 266 of the pad portion A3 and may not be provided in the soft portion A2.

The planarization layer 160 may cover the stretchable line 266 of the rigid portion A1 and the pad portion A3 and may expose the stretchable line 266 of the soft portion A2.

In addition, the planarization layer 160 may not cover and may expose the auxiliary pad 259 of the pad portion A3.

The first contact electrode 162 and the second contact electrode 164 may be provided on the planarization layer 160 of the rigid portion A1.

In the stretchable display device according to another embodiment of the present disclosure, by forming the stretchable line 266 of the same material and on the same layer as the source electrode 152 and the drain electrode 154, the contact hole for connecting the second pad 258 and the stretchable line 266 may be omitted, and the horizontal distance between the stretchable line 266 and/or the second pad 258 and the first contact electrode 162 may be minimized or reduced. Accordingly, the area of the rigid portion A1 may be reduced compared to the embodiment of FIG. 5.

On the other hand, in the embodiment of FIG. 5, since the stretchable line 166 is formed of the same material and on the same layer as the first contact electrode 162 and the second contact electrode 164, the contact hole for connecting the stretchable line 166 and the second pad 158 may be required. In addition, to prevent or reduce the stretchable line 166 from being electrically short-circuited with the first contact electrode 162 and/or the light-emitting element 180 by overlapping the adhesive layer 170 provided on the first and second contact electrodes 162 and 164 with the stretchable line 166, the stretchable line 166 and/or the second pad 158 may be spaced apart from the first contact electrode 162 with a selected distance therebetween.

The horizontal distance between the stretchable line 266 and/or the second pad 258 and the first contact electrode 162 of FIG. 14 may be smaller than the horizontal distance between the stretchable line 166 and/or the second pad 158 and the first contact electrode 162 of FIG. 5. Accordingly, in the stretchable display device according to another embodiment of the present disclosure, the length of the rigid portion A1 may be reduced compared to the previous embodiment, and thus the area of the rigid portion A1 may be decreased, thereby further improving the resolution.

For example, in the stretchable display device according to another embodiment of the present disclosure, the length of the rigid portion A1 may be 99 μm, and the resolution higher than 170 PPI can be implemented.

In the stretchable display device according to another embodiment of the present disclosure, values obtained by calculating the length “b” of the non-rotated soft portion A2, the length “b1” of the rotated soft portion A2, and the rotation angle “θ” for each resolution “R” are shown in Table 2. Here, the length “a” of the rigid portion A1 may be 99 μm, and the separation distance “d” may be 20 μm.

TABLE 2

| [2R(PPI) | c(μm) | a(μm) | b(μm) | θ | bl(μm) |
|---|---|---|---|---|---|
| 150 | 169.3 | 99 | 70.3 | 6.78 | 69.2 |
| 160 | 158.8 | 99 | 59.8 | 7.24 | 58.4 |
| 170 | 149.4 | 99 | 50.4 | 7.69 | 49.1 |
| 180 | 141.1 | 99 | 42.1 | 8.15 | 40.7 |
| 190 | 133.7 | 99 | 34.7 | 8.60 | 33.2 |
| 200 | 127.0 | 99 | 28.0 | 9.06 | 26.4 |
| 210 | 121.0 | 99 | 22.0 | 9.52 | 20.3 |
| 220 | 115.5 | 99 | 16.5 | 9.98 | 14.7 |

In Table 2, when the resolution “R” is 220 PPI, the length “b1” of the rotated soft portion A2 may be smaller than 20 μm. In this case, the area for disposing the stretchable line cannot be secured. Thus, if the resolution “R” is higher than 210 PPI, the stretchable display device cannot be implemented.

Accordingly, in another embodiment of the present disclosure, the resolution of the stretchable display device can be implemented from 150 PPI to 210 PPI. At this time, the rotation angle “θ” may be 5 degrees to 10 degrees, and beneficially, 6 degrees to 10 degrees.

Meanwhile, the base substrate 104 of the soft portion A2, that is, the second base portion 104b may be formed by selectively removing a base layer through a dry etch process after forming a hard mask on the stretchable line 166 or 266 and may be over-etched in some areas so as to be completely etched over the entire display area DA.

At this time, the side surface of the second base portion 104b may be inclined due to the anisotropic property of the dry etch. As the thickness of the base substrate 104 decreases, the side surface of the second base portion 104b has an increased inclination angle. As the inclination angle increases, the design unilateral margin that is a distance between one edge of the stretchable line 166 or 266 and one edge of the hard mask corresponding thereto may be reduced, and the final unilateral margin that is a distance between the one edge of the stretchable line 166 or 266 and one edge of the second base portion 104b may also be decreased.

Accordingly, in the embodiment of the present disclosure, by reducing the thickness of the base substrate 104, the stretching properties of the stretchable line 166 or 266 having the same ratio of length to straight line may be further improved.

The thickness of the base substrate 104 according to the embodiment of the present disclosure may be smaller than 6 μm, and beneficially, may be 2 μm to 5 μm, and the final unilateral margin may be smaller than 2 μm.

For example, when the thickness of the base substrate 104 is about 4 μm and the width of the stretchable line 166 or 266 is about 6 μm, the width of the second base portion 104b may be about 8 μm, and the final unilateral margin may be about 1 μm.

In the previous embodiments, it has been described that the rigid portion A1 and the soft portion A2 are rotated clockwise with respect to the first direction X and the second direction Y, but embodiments of the present disclosure are not limited thereto. In other embodiments, the rigid portion A1 and the soft portion A2 may be rotated counterclockwise with respect to the first direction X and the second direction Y, and in this case, the soft portion A2 and the stretchable line may have a substantially left-right inverted S-like shape.

In the stretchable display device of the present disclosure, by providing the stretchable line of the structure having relatively high stretching properties and repeated stretching reliability, the area of the soft portion may be reduced, and the high resolution can be realized, and by improving the lifetime due to the stretchable line, the production power consumption can be reduced to achieve the low power consumption.

In addition, by rotating the rigid portion, the soft portion, and the stretchable line, the resolution can be improved compared to the device having the same size.

Further, by forming the stretchable line of the same material and on the same layer as the source and drain electrodes, the area of the rigid portion can be further decreased, thereby implementing higher resolution.

It will be apparent to those skilled in the art that various modifications and variations can be made in the display device of the present disclosure without departing from the technical idea or scope of the disclosure. Thus, it is intended that the present disclosure cover the modifications and variations of this disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A stretchable display device, comprising:
a first substrate including a display area and a non-display area;
a plurality of rigid portions provided in the display area on the first substrate and spaced apart from each other in both a first direction and a second direction transverse to the first direction;
a soft portion provided between adjacent rigid portions in the first direction or the second direction; and
a second substrate disposed over the first substrate,
wherein the rigid portion and the soft portion are rotated at a rotation angle with respect to the first direction and the second direction.

2. The stretchable display device of claim 1,
wherein a length of the soft portion is smaller than a length of the rigid portion in the same direction,
wherein the rotation angle is θ and θ=arcsin(d·R/25400), and
wherein “d” is a separation distance between two rigid portions adjacent to each other in the first direction and shifted from each other in the second direction when the rigid portion and the soft portion do not rotate, and “R” is a resolution that is number of pixels per inch.

3. The stretchable display device of claim 1, wherein the rotation angle is equal to or greater than 5 degrees and smaller than or equal to 10 degrees.

4. The stretchable display device of claim 1, wherein the soft portion includes a first straight part, a second straight part, a first curved part, and a second curved part, and
wherein the first and second curved parts are disposed between the first straight part and the second straight part and are disposed convexly in opposite directions.

5. The stretchable display device of claim 4, wherein the soft portion includes an S-like shape.

6. The stretchable display device of claim 1, further comprising:
a pixel provided in each of the plurality of rigid portions and including a plurality of sub-pixels; and
a stretchable line provided in the soft portion and coupling adjacent pixels.

7. The stretchable display device of claim 6, wherein the plurality of sub-pixels and the stretchable line are rotated in a same direction as the rigid portion and the soft portion.

8. The stretchable display device of claim 6, wherein the plurality of sub-pixels does not rotate with respect to the first direction and the second direction, and long sides of the plurality of sub-pixels are parallel to the second direction, and
wherein the stretchable line is rotated in a same direction as the rigid portion and the soft portion.

9. The stretchable display device of claim 6, wherein each of the plurality of sub-pixels includes a thin film transistor and a light-emitting element electrically connected to the thin film transistor, and
wherein the stretchable line is formed of a same material and on a same layer as source and drain electrodes of the thin film transistor.

10. The stretchable display device of claim 1, further comprising a pad portion provided in the non-display area on the first substrate,
wherein the soft portion is further provided between the pad portion and the rigid portion adjacent to the pad portion.

11. The stretchable display device of claim 10, wherein the pad portion is provided as one pattern corresponding to the rigid portions arranged in the first direction, and
wherein a side of the pad portion facing the display area has a prism or saw-toothed shape.

12. A stretchable display device, comprising:
a display panel extended in a first direction and a second direction transverse to the first direction, the display panel including:
a first substrate;
a plurality of rigid portions on the first substrate and spaced apart from each other;
a pad portion provided in the non-display area on the first substrate,
a plurality of soft portions between adjacent rigid portions, wherein the plurality of soft portions is further provided between the pad portion and the rigid portion;
a plurality of sub-pixels disposed to overlap with the plurality of rigid portions from a plan view;
a plurality of stretchable lines including a first group and a second group, the first group of the plurality of stretchable lines coupled between adjacent rigid portions and the second group of the plurality of stretchable lines coupled between a pad portion and a rigid portion of the plurality of rigid portions;
wherein each stretchable line of the plurality includes at least one curved part and at least one straight part, the at least one straight part continuously and contiguously coupled to the at least one curved part,
wherein the at least one straight part of a stretchable line is extended in a third direction, and
wherein the third direction is different from both the first direction and the second direction.

13. The stretchable display device of claim 12, wherein the plurality of rigid portions is spaced apart from each other from a plan view,
wherein a first rigid portion of the plurality includes a first side and a second side when seen from a plan view, and
wherein the first side of the first rigid portion is rotated with respect to the first direction of the display panel at a first inclination angle.

14. The stretchable display device of claim 13, wherein the third direction of the at least one straight part of a stretchable line is rotated with respect to the first direction of the display panel at a second inclination angle.

15. The stretchable display device of claim 14, wherein the first inclination angle and the second inclination angle are identical to each other.

16. The stretchable display device of claim 14, wherein the first inclination angle and the second inclination angle are different from each other.

17. The stretchable display device of claim 14, wherein each sub-pixel of the plurality of sub-pixels has a first side and a second side,
wherein the first side of the sub-pixel is rotated with respect to the first direction of the display panel at a third inclination angle.

18. The stretchable display device of claim 17, wherein the third inclination angle is the same as either the first inclination angle or the second inclination angle.

19. The stretchable display device of claim 14, wherein each sub-pixel of the plurality of sub-pixels has a first side and a second side,
wherein the first side of the sub-pixel is aligned with the first direction of the display panel.

20. The stretchable display device of claim 14, wherein the at least one straight part and the at least one curved part of a stretchable line combine to form an ‘S-like’ shape.

21. The stretchable display device of claim 14, wherein the at least one straight part and the at least one curved part of a stretchable line combine to form an ‘Ω-like’ shape.

22. The stretchable display device of claim 14, wherein the first and second inclination angle is equal to or greater than 5 degrees and smaller than or equal to 10 degrees.

23. The stretchable display device of claim 17, wherein the third inclination angle is equal to or greater than 5 degrees and smaller than or equal to 10 degrees.

24. The stretchable display device of claim 12, wherein the pad portion includes a first group and a second group,
wherein the first group of the pad portion has a rectangular shape from a plan view, and
wherein the second group of the pad portion has a saw-toothed shape from a plan view.
